(19) United States
(12) Patent Application Publication
(10) Pub. No.: US 2026/0090208 A1
(43) Pub. Date: Mar. 26, 2026

(54) DISPLAY DEVICE AND MANUFACTURING METHOD OF DISPLAY DEVICE

(71) Applicant: Sharp Display Technology Corporation, Kameyama City, Mie (JP)

(72) Inventor: Masaki HIRUOKA, Kameyama City, Mie (JP)

(21) Appl. No.: 19/110,501

(22) PCT Filed: Sep. 16, 2022
(86) PCT No.: PCT/JP2022/034736

§ 371 Date: Mar. 11, 2025

(51) Int. Cl. H10K 59/122; H10K 59/12

(52) U.S. Cl. CPC H10K 59/122; H10K 59/1201

(57) ABSTRACT

A display device according to the disclosure includes a light-emitting element located above a substrate, a first bank and a second bank, a first groove recessed into the substrate and located between the first bank and the second bank in a plan view, and an organic film sealing the light-emitting element.

### TECHNICAL FIELD

The disclosure relates to a display device and a manufacturing method of the display device.

### BACKGROUND ART

PTL 1 discloses an organic EL display device provided with a frame-shaped seamless dam groove surrounding a display region and a frame-shaped dam wall surrounding the dam groove in order to dam droplets.

### CITATION LIST

### Patent Literature

PTL 1: WO 2019/163134 A1 (internationally published Aug. 29, 2019)

### SUMMARY

### Technical Problem

In frame narrowing of a display device, sealing of a light-emitting element may be adversely affected due to the fact that an organic film formed from droplets protrudes to the outside of a predetermined region. It is necessary to improve positional accuracy of an outer edge of the organic film and to achieve further frame narrowing of the display device.

### Solution to Problem

A display device according to an aspect of the disclosure includes a substrate, a light-emitting element located above the substrate, a first bank located above the substrate and surrounding the light-emitting element in a plan view, a second bank located above the substrate and surrounding the first bank in a plan view, a first groove recessed into the substrate and located between the first bank and the second bank in a plan view, and an organic film sealing the light-emitting element.

A manufacturing method of a display device according to an aspect of the disclosure includes performing first formation of forming a light-emitting element located above a substrate, a first bank located above the substrate and surrounding the light-emitting element in a plan view, a second bank located above the substrate and surrounding the first bank in a plan view, and a groove recessed into the substrate and located between the first bank and the second bank in a plan view, and performing second formation of forming an organic film sealing the light-emitting element by an ink-jet method after the first formation.

### Advantageous Effects of Disclosure

According to an aspect of the disclosure, the display device can realize further frame narrowing.

### BRIEF DESCRIPTION OF DRAWINGS

FIG. 1 is a plan view illustrating an example of a display device according to an embodiment of the disclosure.

FIG. 2 is a cross-sectional view illustrating an example of the display device illustrated in FIG. 1.

FIG. 3 is a cross-sectional view illustrating an example of the display device illustrated in FIG. 1.

FIG. 4 is a flow diagram illustrating an example of a manufacturing method of a display device according to an embodiment of the disclosure.

FIG. 5 is a cross-sectional view illustrating an example of the manufacturing method of the display device according to an embodiment of the disclosure.

FIG. 6 is a plan view illustrating an example of a display device according to an embodiment of the disclosure.

FIG. 7 is a cross-sectional view illustrating an example of a frame region of the display device illustrated in FIG. 6.

FIG. 8 is a plan view illustrating an example of a display device according to an embodiment of the disclosure.

FIG. 9 is a cross-sectional view illustrating an example of a frame region of the display device illustrated in FIG. 8.

FIG. 10 is a cross-sectional view illustrating an example of a frame region of the display device illustrated in FIG. 8.

FIG. 11 is a plan view illustrating a modification example of a display device according to an embodiment of the disclosure.

### DESCRIPTION OF EMBODIMENTS

### First Embodiment

### Configuration of Display Device

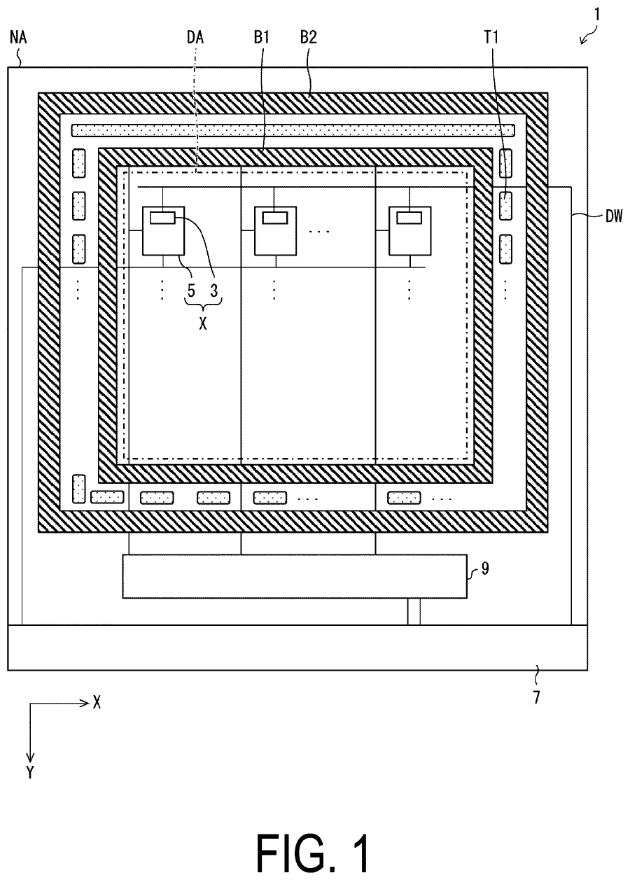

FIG. 1 is a plan view illustrating an example of a display device according to an embodiment of the disclosure. In FIG. 1, a first bank B1, a second bank B2, and a first groove T1 are hatched. As illustrated in FIG. 1, a display device 1 according to the present embodiment includes a display region DA and a frame region NA surrounding the display region DA. A plurality of subpixels X are provided in the display region DA, and at least one of the subpixels X includes a light-emitting element 3 and a pixel circuit 5. The first bank B1, the second bank B2, and the first groove T1 are provided in the frame region NA. The frame region NA may be provided with a terminal portion 7 and/or a driver circuit 9. The display device 1 may include a lead-out wiring line DW led out from the display region DA to the frame region NA. The lead-out wiring line DW may be connected to the terminal portion 7 or the driver circuit 9.

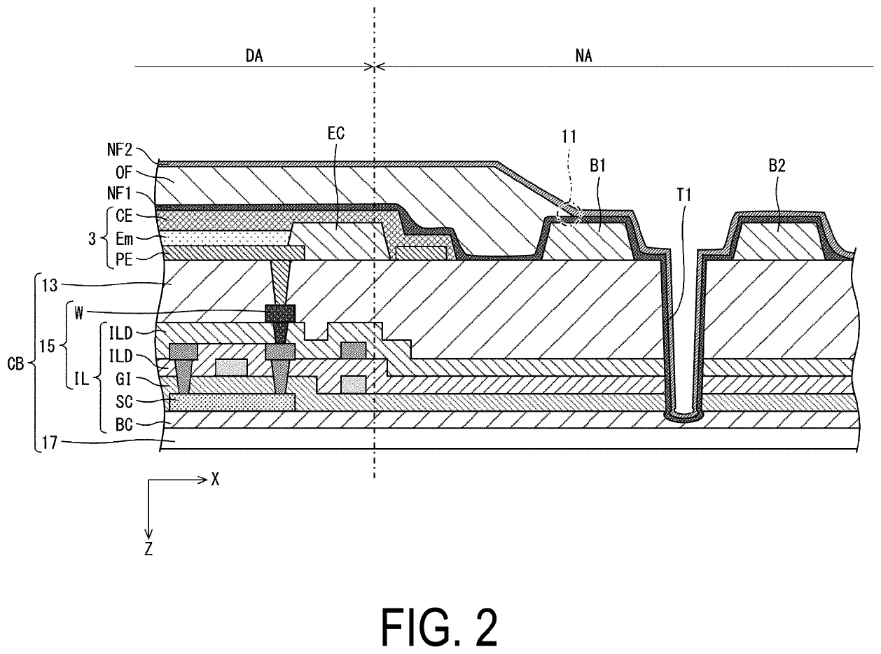

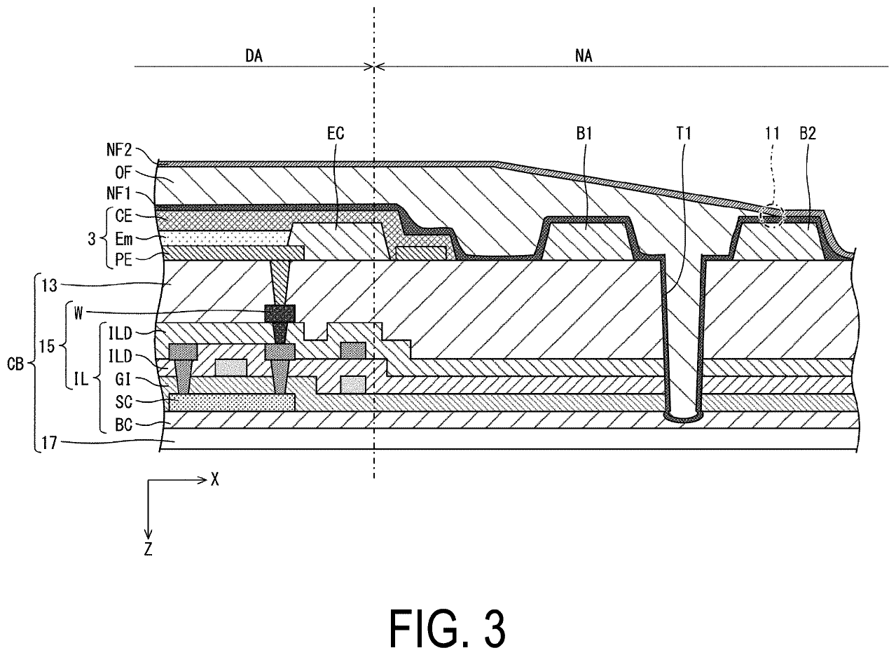

FIGS. 2 and 3 are cross-sectional views illustrating examples of the display device according to an embodiment of the disclosure. As illustrated in FIGS. 2 and 3, the display device 1 includes a substrate CB, the light-emitting element 3, the first bank B1, the second bank B2, the first groove T1, and an organic film OF. One or more light-emitting elements 3 are located above the substrate CB. The first bank B1 is located above the substrate CB and surrounds the light-emitting element 3 in a plan view. The second bank B2 is located above the substrate CB and surrounds the first bank B1 in a plan view. The first groove T1 is recessed into the substrate CB and is located between the first bank B1 and the second bank B2 in a plan view. The organic film OF seals the light-emitting element 3. In the disclosure, the “plan view” means a plan view seen from a direction orthogonal to the substrate CB unless otherwise specified. The direction orthogonal to the substrate CB is the normal direction of the upper surface of the substrate CB and is the Z direction in the drawing.

The display device 1 may include a first inorganic sealing film NF1 and a second inorganic sealing film NF2. The first inorganic sealing film NF1 and the second inorganic sealing film NF2 are formed by vapor-depositing an inorganic material such as silicon nitride, silicon oxide, or silicon oxynitride by a chemical vapor deposition (CVD) method. The first inorganic sealing film NF1 covers the light-emitting element 3, the first bank B1, the first groove T1, and the second bank B2, and is located below the organic film OF. The second inorganic sealing film NF2 covers the organic film OF and is in direct contact with an end portion of the first inorganic sealing film NF1.

The organic film OF is formed by applying a transparent resin having a high visible light transmittance such as an acrylic resin by an ink-jet method or the like. An outer edge 11 of the organic film OF overlaps with the first bank B1 as illustrated in FIG. 2, overlaps with the second bank B2 as illustrated in FIG. 3, or is located between the first bank B1 and the second bank B2 in a plan view. The outer edge 11 may include a portion overlapping with the first bank B1, a portion located between the first bank B1 and the second bank B2, and a portion overlapping with the second bank B2. A portion of the organic film OF may be located in the first groove T1.

The substrate CB includes a flattening film 13. The flattening film 13 is formed by flatly applying a resin such as a polyimide resin by a spin coating method, a bar coating method, or the like. The first groove T1 may be recessed into the flattening film 13 or may extend through the flattening film 13.

The substrate CB includes a layered body 15. The layered body 15 is located below the flattening film 13 and includes one or more wiring lines W and one or more insulating layers IL. The one or more wiring lines W may include, for example, a gate wiring line, a source wiring line, a lead-out wiring line DW, and the like. The one or more insulating layers IL may include, for example, a base coat layer BC, a gate insulating film GI, an interlayer insulating film ILD, and the like. The layered body 15 may be provided with one or more circuit elements, and may be provided with the pixel circuit 5. The first groove T1 may be recessed into the layered body 15 or may extend through the layered body 15.

The base coat layer BC reduces infiltration of oxygen and water from below, and may be formed of a resin such as a polyimide resin. A semiconductor layer SC may be formed of a semiconductor such as single crystal silicon, polycrystalline silicon, or a metal oxide. The gate insulating film GI and the interlayer insulating film ILD may be formed of an inorganic material such as silicon nitride, silicon oxide, or silicon oxynitride. The wiring line W may be formed of a metal such as aluminum, copper, titanium, or silver, or an alloy thereof.

The substrate CB includes a support base 17. The support base 17 is located below the layered body 15. The support base 17 may be a rigid substrate such as a glass substrate, or a flexible substrate such as a resin substrate. The resin substrate may be formed of a polyimide resin or the like. The first groove T1 may be recessed into the support base 17. The support base 17 is often thicker than the layered body 15. For example, a typical thickness of the polyimide resin substrate is 1 μm to 5 μm. Therefore, there is an advantage that the range of control is wide when indenting the first groove T1. In other words, there is an advantage that the allowable manufacturing error with respect to the indenting is large.

The light-emitting element 3 includes a pixel electrode PE, a counter electrode CE opposed to the pixel electrode PE, and a light-emitting layer Em located between the pixel electrode PE and the counter electrode CE. The light-emitting element 3 may include function layers such as a charge transport layer, a charge injection layer, and a charge shielding layer between the pixel electrode PE and the light-emitting layer Em and/or between the counter electrode CE and the light-emitting layer Em. The light-emitting element 3 may be an organic light-emitting diode (OLED) or a quantum dot light-emitting diode (QLED). The pixel electrode PE may be an island electrode provided separately for each light-emitting element 3. The counter electrode CE may be a common electrode provided in common to the plurality of light-emitting elements 3. An edge cover EC covering the edge of the pixel electrode PE may be provided.

The first bank B1 and the second bank B2 are provided in order to dam droplets during formation of the organic film OF. The first bank B1 and the second bank B2 may be formed from a resin such as photosensitive resin using a photoresist method. The cross-sectional shape of the first bank B1 and the second bank B2 may be a forwardly tapered shape or an inversely tapered shape. The first bank B1 and the second bank B2 may have a single-layer structure or a multi-layer structure.

The first groove T1 is provided in order to dam droplets during formation of the organic film OF. The first groove T1 increases the storable volume between the first bank B1 and the second bank B2 and improves damming effect by the first bank B1 and the second bank B2. It should be understood that the first groove T1 is beneficial regardless of whether the organic film OF does not fill the first groove T1 (see FIG. 2) or fills the first groove T1 (see FIG. 3). Due to the increase in the storable volume, the allowable manufacturing error for the organic film OF increases.

When the organic film is formed under the same conditions such as the bank height, the distance between the banks, the errors in the volumes of the droplets, and the errors in the viscosities of the droplets, the configuration according to the disclosure including the first groove T1 has higher positional accuracy of the outer edge 11 of the organic film OF than the configuration without the first groove T1. Therefore, the probability that the outer edge 11 of the organic film OF is in the predetermined position range is improved by the first groove T1, and the manufacturing yield of the display device 1 is improved. Here, the predetermined position range may be a range from a position where the outer edge 11 of the organic film OF overlaps with the first bank B1 as illustrated in FIG. 2 to a position where the outer edge 11 overlaps with the second bank B2 as illustrated in FIG. 3 in a plan view. Therefore, the distance between the first bank B1 and the second bank B2 can be reduced, and the frame narrowing of the display device 1 can be achieved.

The first groove T1 can further reduce a step of the organic film OF called a “dog ear”. When the droplets are dammed, the droplets may wet-spread toward the outer edge 11, the vicinity of the outer edge 11 may rise, and a step in which the end portion of the organic film OF is thicker than the central portion may be generated. This step is called a “dog ear”. Since a part of the liquid is filled in the first groove T1, the dog ear can be reduced. The deeper the first groove T1 is, the more beneficial it is for dog ear reduction. It is beneficial that the first groove T1 extends through the flattening film 13 and the layered body 15 and is recessed into the support base 17.

A plurality of grooves including the first groove T1 may be provided between the first bank B1 and the second bank B2. The plurality of grooves may be disposed so as to surround the first bank B1.

### Manufacturing Method of Display Device

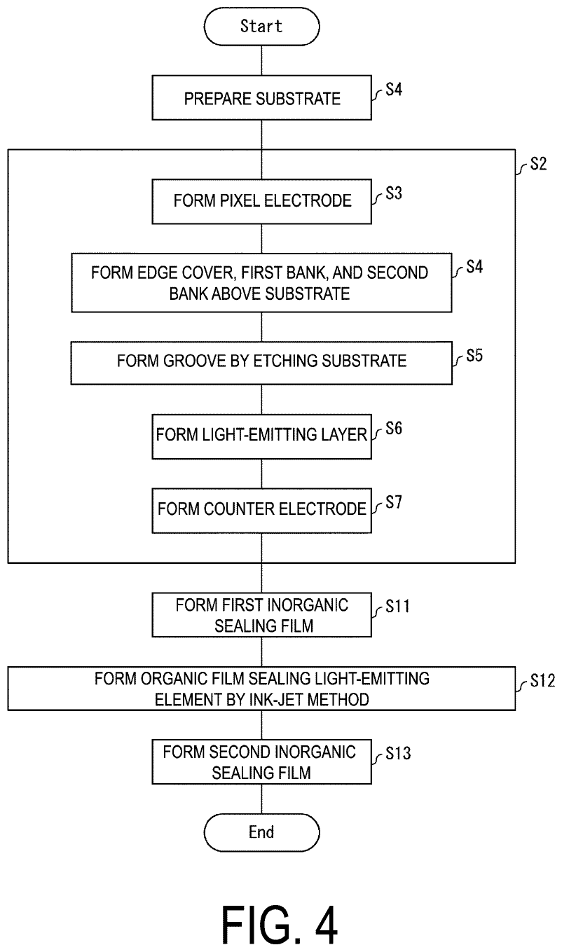

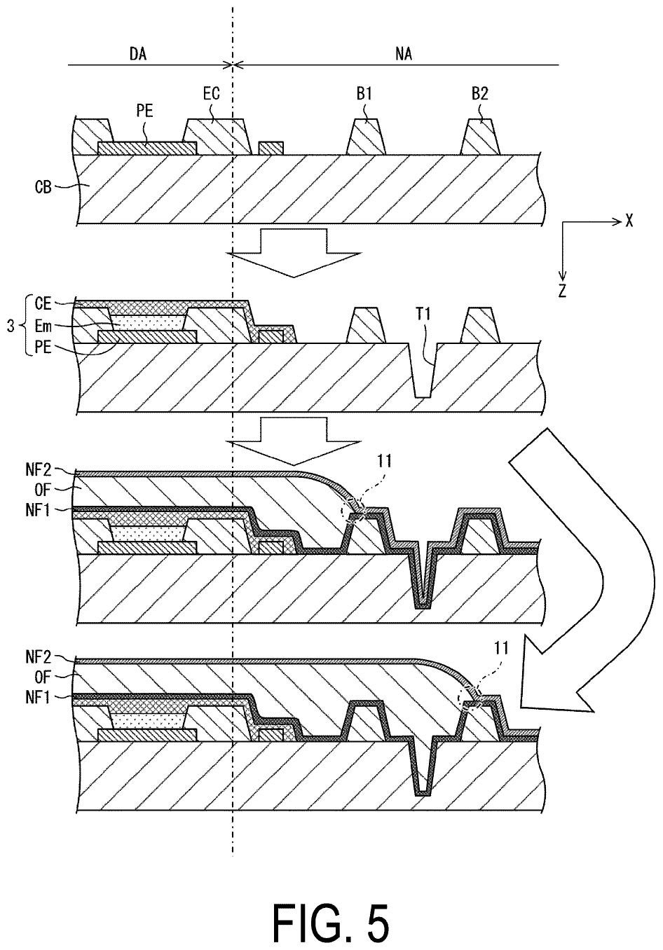

FIG. 4 is a flow diagram illustrating an example of a manufacturing method of a display device according to an embodiment of the disclosure. FIG. 5 is a cross-sectional view illustrating an example of the manufacturing method of the display device according to an embodiment of the disclosure. As illustrated in FIGS. 4 and 5, first, the substrate CB is prepared (step S1), and there formed are the light-emitting element 3 located above the substrate CB, the first bank B1 located above the substrate CB and surrounding the light-emitting element 3 in a plan view, the second bank B2 located above the substrate CB and surrounding the first bank B1 in a plan view, and the groove recessed into the substrate CB and located between the first bank B1 and the second bank B2 in a plan view (step S2, first process). The groove formed in step S2 includes the first groove T1. It should be understood that in step S2, the light-emitting element 3, the first bank B1, the first groove T1, and the second bank B2 may be formed in any order with respect to each other, and may be formed in an order other than the order described below with reference to FIGS. 4 and 5.

In step S2, for example, as illustrated in the uppermost stage of FIG. 5, the pixel electrode PE is formed on the substrate CB (step S3), and the edge cover EC, the first bank B1, and the second bank B2 are formed above the substrate CB (step S4). In step S4, the edge cover EC is formed to cover the edge of the pixel electrode PE. The first bank B1 is formed such that the first bank B1 surrounds the pixel electrode PE. The second bank B2 is formed such that the second bank B2 surrounds the first bank B1. In step S4, it is beneficial to form at least a part of the first bank B1 and at least a part of the second bank B2 and at least a part of the edge cover EC in the same process. For example, a photosensitive resin liquid may be applied onto the substrate CB, and the photosensitive resin liquid may be solidified using a photolithography method so as to form the first bank B1, the second bank B2, and the edge cover EC. For example, the first bank B1, the second bank B2, and the edge cover EC may be formed by forming a resin layer on the substrate CB and etching the resin layer.

Subsequently, as illustrated in the second stage from the top in FIG. 5, by etching the substrate CB, the first groove T1 is formed so as to be located between the first bank B1 and the second bank B2 (step S5). In step S5, dry etching is beneficial. Dry etching causes less side etching than wet etching, and is suitable for deep etching. Grooves other than the first groove T1 may also be formed simultaneously with the first groove T1. Then, the light-emitting layer Em and the counter electrode CE are sequentially formed above the pixel electrode PE (steps S6 to S7).

After step S2, as illustrated in the third stage from the top and the lowermost stage in FIG. 5, a first inorganic sealing film NF1 sealing the light-emitting element 3 is formed by CVD so as to cover the light-emitting element 3, the first bank B1, the first groove T1, and the second bank B2 (step S11). The organic film OF sealing the light-emitting element 3 is formed on the first inorganic sealing film NF1 by an ink-jet method (step S12, second process). In step S8, the droplets of the organic film OF which are dropped wet-spread over the first inorganic sealing film NF1 and are dammed by any one of the first bank B1, the first groove T1, and the second bank B2. The droplets may or may not fill the first groove T1. Subsequently, the second inorganic sealing film NF2 further sealing the light-emitting element 3 is formed by CVD so as to cover the organic film OF (step S13). Step S11 to step S13 are performed after step S2.

### Second Embodiment

Another embodiment of the disclosure will be described below. Note that, members having the same functions as those of the members described in the above-described embodiments will be denoted by the same reference numerals and signs, and the description thereof will not be repeated for the sake of convenience of description.

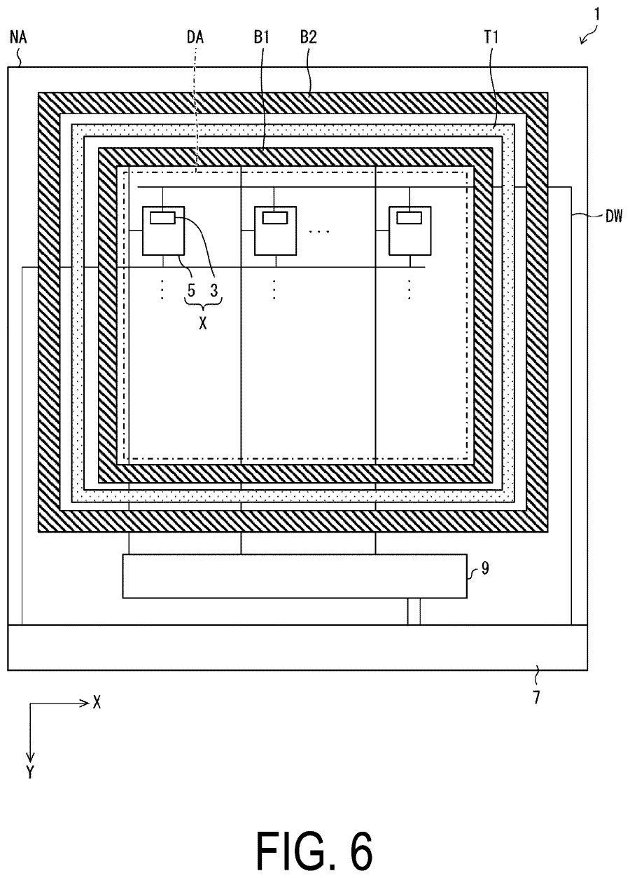

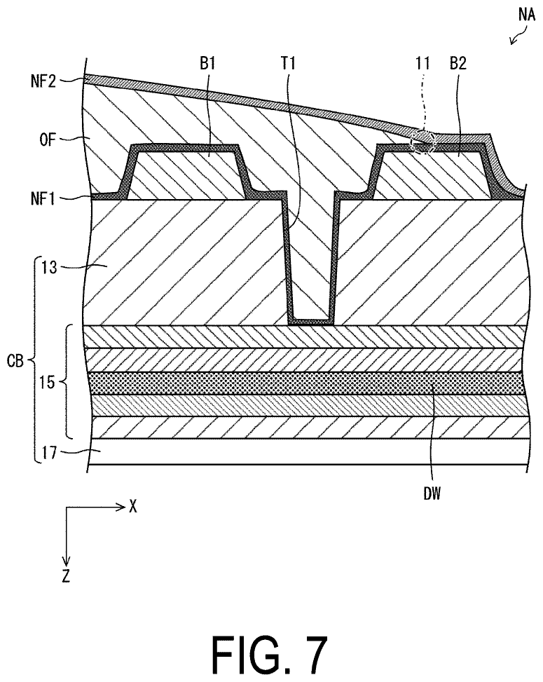

FIG. 6 is a plan view illustrating an example of a display device according to an embodiment of the disclosure. FIG. 7 is a cross-sectional view illustrating an example of a frame region of the display device according to an embodiment of the disclosure. As illustrated in FIG. 6, a first groove T1 according to the present embodiment surrounds a first bank B1 in a plan view. As illustrated in FIG. 7, it is beneficial that a first groove T1 does not extend through a layered body 15 in order to lead out a lead-out wiring line DW from a display region DA to a frame region NA without re-connection or additional connection processing.

### Third Embodiment

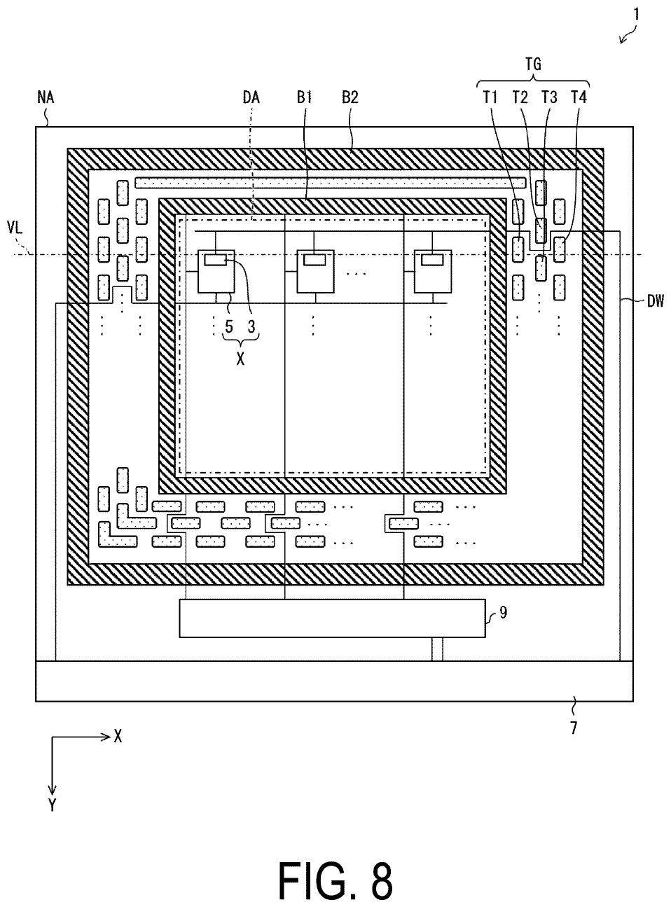

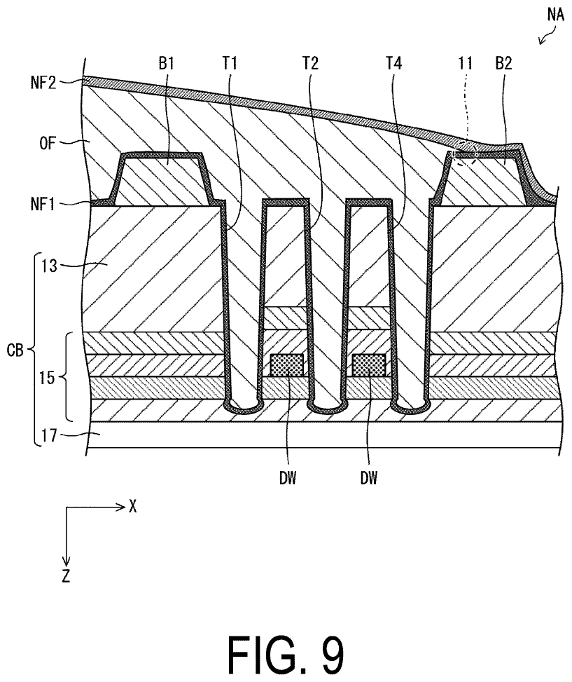

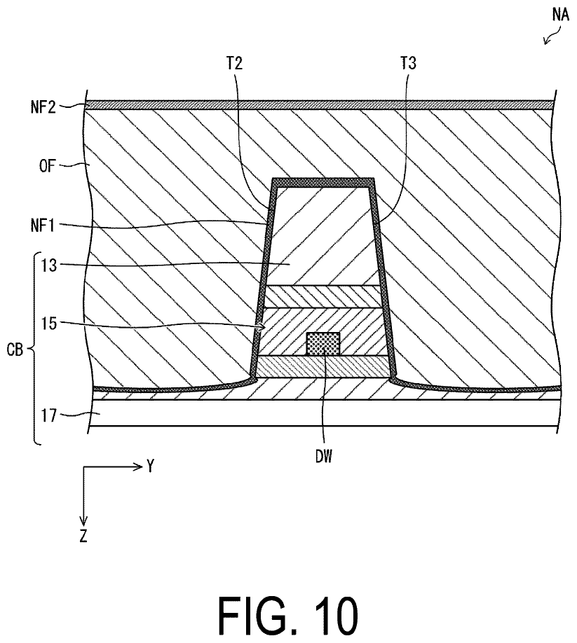

FIG. 8 is a plan view illustrating an example of a display device according to an embodiment of the disclosure. FIGS. 9 and 10 are cross-sectional views illustrating an example of a frame region of a display device according to an embodiment of the disclosure. As illustrated in FIGS. 8, 9, and 10, a display device 1 according to the present embodiment includes a first groove T1, and further includes a second groove T2, a third groove T3, and a fourth groove T4. The second groove T2 and the third groove T3 are located on the side of a second bank B2 with respect to the first groove T1 in a plan view, and are recessed into the substrate CB. The fourth groove T4 is located on the side of the second bank B2 with respect to the second groove T2 and the third groove T3 in a plan view, and is recessed into the substrate CB. A lead-out wiring line DW passes between the first groove T1 and the second groove T2, between the second groove T2 and the third groove T3, and between the second groove T2 and the fourth groove T4.

Since the lead-out wiring line DW passes through the space between the grooves, even when the first groove T1 extends through a layered body 15, the lead-out wiring line DW can be led out from the display region DA to the frame region NA without re-connection or additional connection processing.

The first groove T1, the second groove T2, the third groove T3, and the fourth groove T4 may be disposed such that spaces between the grooves are not aligned on a straight line from the first bank B1 to the second bank B2. For example, the first groove T1, the second groove T2, and the third groove T3 may be disposed such that a virtual line VL passing between the second groove T2 and the third groove T3 and orthogonal to the first bank B1 passes through the first groove T1 in a plan view. The fourth groove T4 may be disposed such that the virtual line VL passes through the fourth groove T4. That is, the arrangement of a groove group TG may be a so-called alternate arrangement. Each of the first groove T1 to the fourth groove T4 may have an elongated shape whose long axis is parallel to the first bank B1 in a plan view.

The display device 1 may include the groove group TG including the first groove T1 to the fourth groove T4. The groove group TG includes a plurality of grooves and may be disposed between the first bank B1 and the second bank B2 so as to surround the first bank B1.

### Modification Example

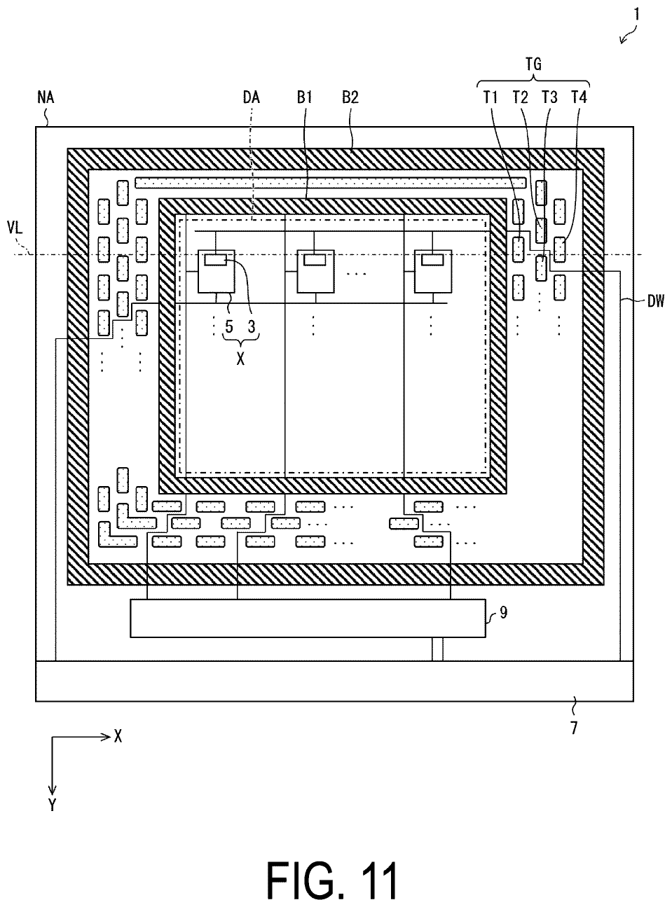

FIG. 11 is a plan view illustrating a modification example of a display device according to an embodiment of the disclosure. As illustrated in FIG. 11, the lead-out wiring line DW may pass between the first groove T1 and the second groove T2, between the second groove T2 and the third groove T3, and between the third groove T3 and the fourth groove T4.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

1. A display device comprising:
a substrate;
a light-emitting element located above the substrate;
a first bank located above the substrate and surrounding the light-emitting element in a plan view;
a second bank located above the substrate and surrounding the first bank in a plan view;
a first groove recessed into the substrate and located between the first bank and the second bank in a plan view; and
an organic film sealing the light-emitting element.

2. The display device according to claim 1,
wherein an outer edge of the organic film overlaps with the first bank or the second bank or is located between the first bank and the second bank in a plan view.

3. The display device according to claim 1,
wherein a portion of the organic film is located in the first groove.

4. The display device according to claim 1,
wherein the substrate includes a flattening film, and
the first groove extends through the flattening film.

5. The display device according to claim 4,
wherein the substrate includes a layered body located below the flattening film and including a wiring line and an insulating layer, and
the first groove extends through the layered body.

6. The display device according to claim 5,
wherein the substrate includes a support base located below the layered body, and
the first groove is recessed into the support base.

7. The display device according to claim 1,
wherein the first groove surrounds the first bank in a plan view.

8. The display device according to claim 5, further comprising:
a second groove and a third groove located on a side of the second bank with respect to the first groove in a plan view and recessed into the substrate,
wherein the wiring line includes a lead-out wiring line passing between the first groove and the second groove, and between the second groove and the third groove.

9. The display device according to claim 8,
wherein a virtual line passing between the second groove and the third groove and orthogonal to the first bank passes through the first groove in a plan view.

10. The display device according to claim 8, further comprising:
a groove group including the first groove to the third groove,
wherein the groove group is disposed between the first bank and the second bank to surround the first bank.

11. The display device according to claim 1, further comprising:
a first inorganic sealing film covering the light-emitting element, the first bank, the first groove, and the second bank and located below the organic film; and
a second inorganic sealing film covering the organic film and in direct contact with an end portion of the first inorganic sealing film.

12. The display device according to claim 1,
wherein the light-emitting element includes an organic light-emitting diode or a quantum dot light-emitting diode.

13. A manufacturing method of a display device comprising:
performing first formation of forming a light-emitting element located above a substrate, a first bank located above the substrate and surrounding the light-emitting element in a plan view, a second bank located above the substrate and surrounding the first bank in a plan view, and a groove recessed into the substrate and located between the first bank and the second bank in a plan view; and
performing second formation of forming an organic film sealing the light-emitting element by an ink-jet method after the first formation.

14. The manufacturing method of a display device according to claim 13,
wherein the groove is formed by etching the substrate in the first formation.

15. The manufacturing method of a display device according to claim 13,
wherein the first bank is formed to surround a pixel electrode of the light-emitting element in the first formation.

16. The manufacturing method of a display device according to claim 13,
wherein at least a part of the first bank and at least a part of the second bank, and at least a part of an edge cover covering an edge of a pixel electrode of the light-emitting element, are formed in the same formation in the first formation.
